(19) United States
(12) Patent Application Publication
(10) Pub. No.: US 2021/0200042 A1
(43) Pub. Date: Jul. 1, 2021

(54) ARRAY SUBSTRATE

(71) Applicant: HKC Corporation Limited, Shenzhen City, Guangdong (CN)

(72) Inventor: Beizhou HUANG, Shenzhen City, Guangdong (CN)

(21) Appl. No.: 16/068,189

(22) PCT Filed: Dec. 20, 2017
(86) PCT No.: PCT/CN2017/117337

§ 371 Date: Jul. 5, 2018

(30) Foreign Application Priority Data
Oct. 12, 2017 (CN) 201710948850.8

(51) Int. Cl. G02F 1/1362; H01L 27/02; H01L 27/12

(52) U.S. Cl. CPC G02F 1/136204; H01L 27/0292; G02F 1/1368; G02F 1/136286; G02F 2202/22; H01L 27/1244

(57) ABSTRACT

The invention provides an array substrate, which comprises: a substrate including a display area and a wiring area, wherein the display area includes a plurality of scan lines and a plurality of data lines; a plurality of pixel units disposed at intersections of the scan lines and the data lines; and an electrostatic discharge protection circuit, coupled to the scan lines.

### BACKGROUND OF THE INVENTION

### Field of Invention

The present invention relates to an array substrate, especially an array substrate of an electrostatic discharge protection circuit coupled to the scan lines.

### Description of Related Art

Static electricity is resulted from an imbalance of electric charge within or on the surface of a material, to form a positive electric charge or negative electric charge. When the charge is able to move and there is a discharge between different voltage levels, an electrostatic discharge (ESD) is generated. In the production/manufacturing process of the thin film transistor liquid crystal display (TFT-LCD; for example, an active matrix liquid crystal display), different layers are coated on a glass substrate, and the different layer coatings may be performed/processed at different equipment's and/or chambers.

In general, an end of a scan line in the LCD is floating; that is, the end of the scan line is not connected to any circuit or component for preventing static charge. However, in the layer coating and transmission processes of the glass substrate, a large amount of electrostatic charge is unavoidably generated to form a high voltage difference, which is apt to penetrate the layer near the contact place, to cause a problem that the substrate or film layer cannot be repaired.

### SUMMARY OF THE INVENTION

In view of resolving the above technical issues, the present invention is to provide an array substrate including an electrostatic discharge protection circuit, to discharge the electrostatic charge by the electrostatic discharge protection circuit before cell manufacturing process of the array substrate.

The objects and technical solutions of the present invention are implemented by following technical ways and means. In one perspective, the present invention provides an array substrate, comprising: a substrate, including a display area and a wiring area, the display area including a plurality of scan lines and a plurality of data lines, and a plurality of pixel units are disposed at intersections of the scan lines and the data lines; and an electrostatic discharge protection circuit, coupled to the scan lines.

The object and solution for the aforementioned technical problem according to the present invention, can be also achieved by following embodiments and technical details.

In one embodiment of the present invention, the electrostatic discharge protection circuit is an anti-static ring circuit.

In one embodiment of the present invention, the electrostatic discharge protection circuit is a point discharge circuit.

In one embodiment of the present invention, the electrostatic discharge protection circuit includes a plurality of discharge units disposed in parallel and insulated from each other in a first direction. Each of the discharge units includes two conduction pieces separated from each other in a second direction and disposed by facing each other, wherein the second direction is perpendicular to the first direction, and two facing ends of the two conduction pieces are respectively two point tips.

In one embodiment of the present invention, the spacing distances between the point tips of the two conduction pieces of the discharge units in the second direction, are the same, different, or partly the same.

In one embodiment of the present invention, a material of the electrostatic discharge protection circuit is equivalent to a material of a conductive line.

In one embodiment of the present invention, a material of the conduction pieces includes: molybdenum, titanium, aluminum, copper, a combination of two or more thereof.

In one embodiment of the present invention, the point tips are triangular.

In one embodiment of the present invention, the electrostatic discharge protection circuit is disposed in the wiring area.

The another object of the present invention is to provide an array substrate, which comprises: a substrate, including a display area and a wiring area, the display area including a plurality of scan lines and a plurality of data lines, and a plurality of pixel units are disposed at intersections of the scan lines and the data lines; and an electrostatic discharge protection circuit, disposed in the wiring area and coupled to the scan lines; wherein, the electrostatic discharge protection circuit includes one electrostatic discharge circuit to be simultaneously coupled to a plurality of scan lines, or includes a plurality of electrostatic discharge circuits to be correspondingly coupled to a plurality of scan lines. In one embodiment, the electrostatic discharge protection circuit includes a point discharge circuit or an anti-static ring circuit. The point discharge circuit includes a plurality of discharge units disposed in parallel and insulated from each other in a first direction. Each of the discharge units includes two conduction pieces separated from each other in a second direction and disposed by facing each other, wherein the second direction is perpendicular to the first direction, and two facing ends of the two conduction pieces are respectively two point tips. The spacing distances between the discharge units in the first direction are the same, different, or partly the same. The spacing distances between the point tips of the two conduction pieces of the discharge units in the second direction, are the same, different, or partly the same.

The present invention can discharge the electrostatic charge which is generated in the layer coating and transmission processes of the substrate, to prevent high voltage difference caused by the large amount of electrostatic charge from penetrating the layer near the contact. Further, after the cell manufacturing process of the display panel, connections between the electrostatic discharge protection circuit and the ends of the scan lines can be cut by a laser cutting, so that the scan lines can be in a normal operation without affecting the open area nor the border width of the display panel, and there is little impact on a production capacity of the production line. By the present invention, a related modification of the circuit is simple and easy, and the circuit reliability is much improved. Further, the present invention can be applied to the production of various size panels, so that the present invention has a high applicability.

### BRIEF DESCRIPTION OF THE DRAWINGS

FIG. 1a illustrates a layout of an exemplary array substrate according to the present invention.

FIG. 1b illustrates a floating layout of scan lines of an exemplary array substrate according to the present invention.

FIG. 2a illustrates an electrostatic discharge protection circuit of an array substrate according to one embodiment of the present invention method.

FIG. 2b illustrates an electrostatic discharge protection circuit of an array substrate according to one embodiment of the present invention method.

FIG. 2c illustrates an electrostatic discharge protection circuit of an array substrate according to one embodiment of the present invention method.

FIG. 2d illustrates a circuit cut of an array substrate according to one embodiment of the present invention method.

FIG. 2e illustrates an electrostatic discharge protection circuit according to one embodiment of the present invention method.

### DESCRIPTION OF THE PREFERRED EMBODIMENTS

The drawings as referred to throughout the description of the present invention are examples for implementing the objects of the present invention. The orientation words or terms used in the description of the present invention, such as “above”, “under”, “forward”, “backward”, “left”, “right”, “inner”, “outer”, “side”, etc. are examples in the drawings for illustrative purpose only, or just show the interrelations between the components, but not to be construed as limitations to the scope of the present invention.

The drawings and the description of the present invention are deemed to be examples but not limitations essentially. In the drawings, components or elements having similar or same structure are marked with the same numbers. In addition, sizes and thicknesses of every component or element are just examples, but not drawn according to actual scale and not read as limitations to the scope of the present invention.

In drawings of the present invention, sizes and thicknesses of layers, films, panels, or regions are emphasized for clearness, easy to describe and easy to understand. Therefore, some layers, films, or regions are emphasized but not drawn according to their actual scales. It is to be understood that, for example, when one of the components of layers, films, regions, or substrate are “on” another component of layers, films, regions, or substrate, the one of the components of layers, films, regions, or substrate could be adjacent on another component of layers, films, regions, or substrate directly, or there could be other inter-components of layers, films, regions, or substrate set therebetween.

Furthermore, in the description of the present invention, a word “comprising” or “including” is construed to comprise or include the related components, but not exclude other components, except there is clearly opposite word or description in the present invention. And, in the description of the present invention, a word “on” is construed to be above or under a target component, but not construed to be limited on a top of the target component in vertical or gravity direction.

For further clarifying the technical solutions or functions of the present invention to implement the objects of the present invention, an array substrate, and their specific implementations, structures, features, and functions, according to a preferred embodiment of the present invention will be apparent from the following detailed description, which proceeds with reference to the accompanying drawings.

The present invention is applied to a display panel, which can include a first substrate and a second substrate. For example, the first and the second substrate can include an active array (thin film transistor, TFT) substrate, and a color filter (CF) substrate. However, in some embodiments, the active array and the color filter (CF) can be formed on the same substrate.

In some embodiments, the display panel according to the present invention can include, for example, a liquid crystal display (LCD) panel. Or, the display panel according to the present invention is not limited to the liquid crystal display (LCD) panel, but can include: an organic light-emitting diode (OLED) display panel, a white organic light-emitting diode (W-OLED) display panel, a quantum dot light-emitting diode (QLED) display panel, a plasma display panel, a curved display panel, or other types of the display panels.

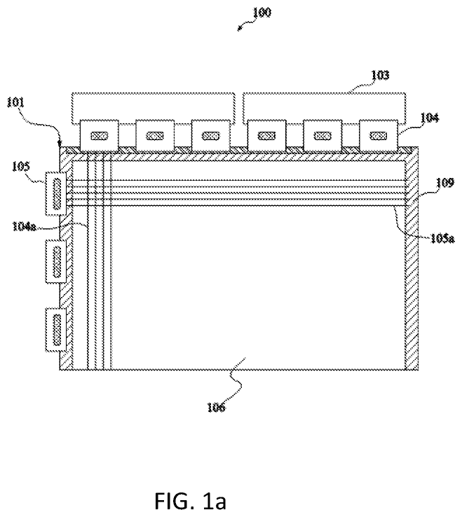

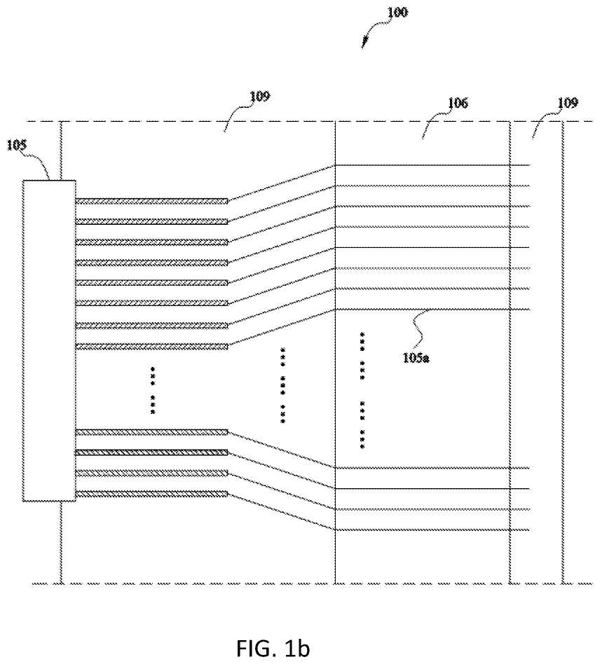

FIG. 1a illustrates a layout of an exemplary array substrate according to the present invention. In FIG. 1a, an array substrate 100 comprises: a substrate 101, including a display area 106 and a wiring area 109; a printed circuit board 103, electrically coupled to the source driving units 104 and gate driving units 105; the source driving units 104 and the gate driving units 105, respectively coupled to data lines 104a and scan lines 105a in the display area. In some embodiments, the gate driving units 105 and the source driving units 104 include, for example, but are not limited to the chip on film package.

FIG. 1b illustrates a floating layout of scan lines of an exemplary array substrate according to the present invention. In general, during the manufacturing process of the display panel, ends of the scan lines are floating; that is, the ends of the scan lines are not connected to any circuit or component for preventing static charge. However, in the layer coating and transmission processes of the glass substrate, a large amount of electrostatic charge is unavoidably generated. In the probe/pin contact process during the glass substrate transmission, a high voltage difference due to the large amount of electrostatic charge is generated near the contact. This high voltage difference is apt to penetrate the layer near the contact, to cause a problem that the substrate or film layer cannot be repaired.

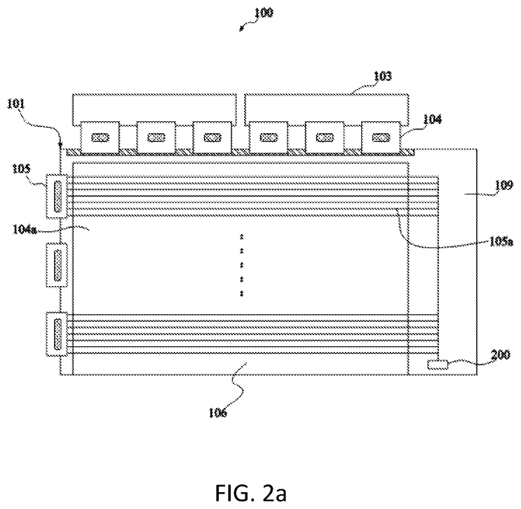

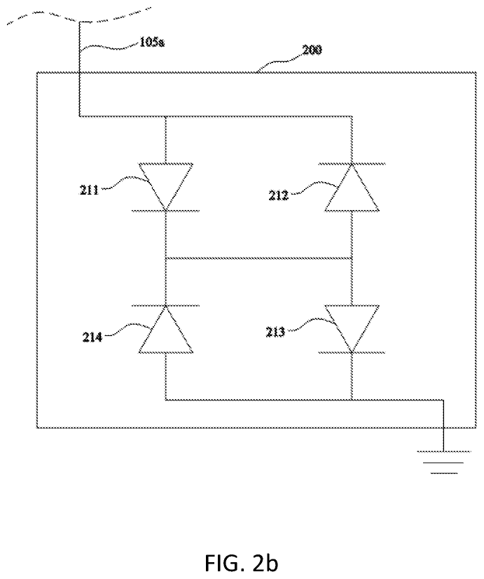

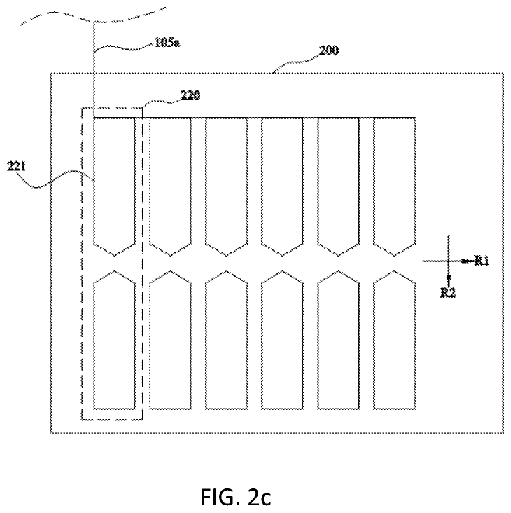

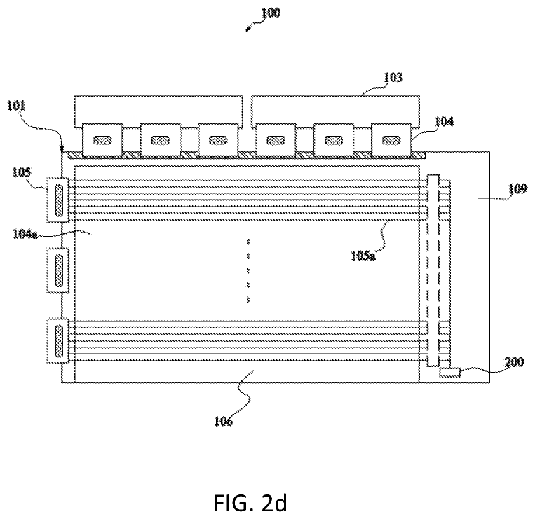

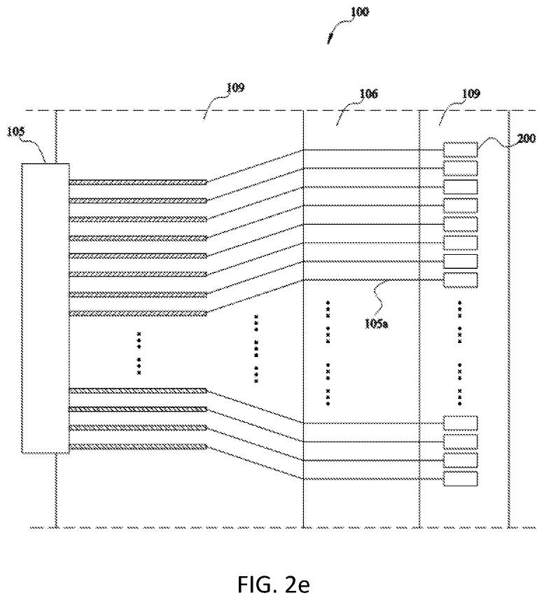

FIG. 2a illustrates an electrostatic discharge protection circuit of an array substrate according to one embodiment of the present invention method. In FIG. 2a, the present invention provides an array substrate 100, comprising: a substrate 101, including a display area 106 and a wiring area 109, the display area 106 including a plurality of scan lines 105a and a plurality of data lines 104a, and a plurality of pixel units (not shown) are disposed at intersections of the scan lines 105a and the data lines 104a; and an electrostatic discharge protection circuit 200, coupled to the scan lines 105a.

In some embodiments, the electrostatic discharge protection circuit 200 is disposed in the wiring area 109.

FIG. 2b illustrates an electrostatic discharge protection circuit of an array substrate according to one embodiment of the present invention method. In one embodiment, the electrostatic discharge protection circuit of FIG. 2b, can be equivalent to the electrostatic discharge protection circuit 200 of FIG. 2a. Please refer to FIG. 2b, wherein the electrostatic discharge protection circuit 200 can be an anti-static ring circuit.

In some embodiment, the anti-static ring circuit includes a ring circuit composed of four diodes, wherein the ring circuit includes an input end and an output end. In one embodiment, the input end is coupled to the scan lines 105a, and the output end is coupled to ground GND. When the static charge received by the input end is a positive charge, the static charge is transmitted through a first diode 211 and a third diode 213, to the ground GND. When the static charge received by the input end is a negative charge, the static charge is transmitted through a second diode 212 and a fourth diode 214, to the ground GND.

FIG. 2c illustrates an electrostatic discharge protection circuit of an array substrate according to one embodiment of the present invention method. Please refer to FIG. 2a to FIG. 2c simultaneously for better understanding. Please refer to FIG. 2c, wherein the electrostatic discharge protection circuit 200 can be a point discharge circuit.

In some embodiments, the point discharge circuit includes a plurality of discharge units 220, disposed in parallel and insulated from each other in a first direction R1. Each of the discharge units 220 includes two conduction pieces 211 separated from each other in a second direction R2 and disposed by facing each other, wherein the second direction is perpendicular to the first direction, and two facing ends of the two conduction pieces are respectively two point tips.

In some embodiments, the discharge units are separated from each other by a same spacing distance in the first direction.

In some embodiments, the discharge units are respectively separated from each other in different spacing distances in the first direction.

In some embodiments, the discharge units are respectively separated from each other in a plurality of spacing distances, wherein the spacing distances are partly the same in the first direction.

In some embodiments, the spacing distances between the point tips of the two conduction pieces of the discharge units, are the same in the second direction.

In some embodiments, the spacing distances between the point tips of the two conduction pieces of the discharge units, are different in the second direction.

In some embodiments, the spacing distances between the point tips of the two conduction pieces of the discharge units, are partly the same in the first direction.

In some embodiments, a material of the electrostatic discharge protection circuit is equivalent to a material of a conductive line.

In some embodiments, a material of the conduction pieces includes: molybdenum, titanium, aluminum, copper, or a combination of two or more thereof.

In some embodiments, the point tips are triangular.

In some embodiments, the array substrate includes a plurality of metal layers, wherein the point discharge circuit can be manufactured in the same metal layer.

In some embodiments, the array substrate includes a plurality of metal layers, wherein the point discharge circuit can be manufactured in different metal layers.

In some embodiments, the array substrate includes a plurality of metal layers, wherein the point discharge circuit can be manufactured in the layers which are partly the same.

FIG. 2d illustrates a circuit cut of an array substrate according to one embodiment of the present invention method. Please refer to FIG. 2a to FIG. 2d simultaneously for better understanding purpose. Please refer to FIG. 2d, after a cell manufacturing process of the display panel, connections between the electrostatic discharge protection circuit and the ends of the scan lines can be cut by a laser cutting. Afterwards, the scan lines can be in a normal operation.

In the one embodiment of FIG. 2a, the electrostatic discharge protection circuit includes one electrostatic discharge circuit to be simultaneously coupled to a plurality of scan lines.

FIG. 2e illustrates an electrostatic discharge protection circuit according to one embodiment of the present invention method. Please refer to FIG. 2a to FIG. 2e simultaneously for better understanding purpose. In FIG. 2e, the electrostatic discharge protection circuit includes a plurality of electrostatic discharge circuits to be correspondingly coupled to a plurality of scan lines.

In one embodiment, the present invention provides an array substrate, which comprises: a substrate, including a display area and a wiring area, the display area including a plurality of scan lines and a plurality of data lines, and a plurality of pixel units are disposed at intersections of the scan lines and the data lines; and an electrostatic discharge protection circuit, disposed in the wiring area and coupled to the scan lines.

The electrostatic discharge protection circuit includes the one electrostatic discharge circuit to be simultaneously coupled to a plurality of scan lines, or the plural electrostatic discharge circuits to be correspondingly coupled to a plurality of scan lines. In one embodiment, the electrostatic discharge protection circuit includes the point discharge circuit or the anti-static ring circuit. The point discharge circuit includes the plural discharge units disposed in parallel and insulated from each other in the first direction. Each of the discharge units includes the two conduction pieces separated from each other in the second direction and disposed by facing each other, wherein the second direction is perpendicular to the first direction, and the two facing ends of the two conduction pieces are respectively two point tips. The spacing distances between the discharge units in the first direction are the same, different, or partly the same. The spacing distances between the point tips of the two conduction pieces of the discharge units in the second direction, are the same, different, or partly the same.

The present invention can discharge the electrostatic charge generated in the layer coating and transmission processes of the substrate, to prevent a high voltage difference caused by the large amount of electrostatic charge from penetrating the layer near the contact. Further, after the cell manufacturing process of the display panel, connections between the electrostatic discharge protection circuit and the ends of the scan lines can be cut by a laser cutting, so that the scan lines can be in the normal operation with little impact on a production capacity of the production line. By the present invention, a related modification of the circuit is simple and easy, and the circuit reliability is much improved. Further, the present invention can be applied to the production of various size panels, so that the present invention has a high applicability.

“In some embodiments of the present invention” and “In a variety of embodiments of the present invention” are used repeatedly through the description. They usually mean different embodiments. However, they can also mean the same embodiments. “Comprising”, “having” and “including” are synonyms, except it is noted to be different or has other meanings before and after its description.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. It is not limited to each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment.

What is claimed is:

1. An array substrate, comprising
a substrate, including a display area and a wiring area, wherein the display area includes a plurality of scan lines and a plurality of data lines, and a plurality of pixel units are disposed at intersections of the scan lines and the data lines; and
an electrostatic discharge protection circuit, coupled to the scan lines.

2. The array substrate of claim 1, wherein the electrostatic discharge protection circuit is an anti-static ring circuit.

3. The array substrate of claim 1, wherein the electrostatic discharge protection circuit is a point discharge circuit.

4. The array substrate of claim 3, wherein the electrostatic discharge protection circuit includes a plurality of discharge units disposed in parallel and insulated from each other in a first direction.

5. The array substrate of claim 4, wherein the discharge units are separated from each other by a same spacing distance in the first direction.

6. The array substrate of claim 4, wherein the discharge units are respectively separated from each other by different spacing distances in the first direction.

7. The array substrate of claim 4, wherein the discharge units are respectively separated from each other in a plurality of spacing distances, wherein a portion of the spacing distances are the same in the first direction.

8. The array substrate of claim 4, wherein each of the discharge units includes two conduction pieces separated from each other in a second direction, and disposed by facing each other.

9. The array substrate of claim 8, wherein the second direction is perpendicular to the first direction.

10. The array substrate of claim 8, wherein two facing ends of the two conduction pieces, are respectively two point tips.

11. The array substrate of claim 10, wherein the spacing distances between the point tips of the two conduction pieces of the discharge units, are the same in the second direction.

12. The array substrate of claim 10, wherein the spacing distances between the point tips of the two conduction pieces of the discharge units, are different in the second direction.

13. The array substrate of claim 10, wherein the spacing distances between the point tips of the two conduction pieces of the discharge units, are partly the same in the first direction.

14. The array substrate of claim 10, wherein the point tips are triangular.

15. The array substrate of claim 8, wherein a material of the conduction pieces includes: molybdenum, titanium, aluminum, copper, a combination of two or more thereof.

16. The array substrate of claim 1, wherein a material of the electrostatic discharge protection circuit is equivalent to a material of the lines.

17. The array substrate of claim 1, wherein the electrostatic discharge protection circuit is disposed in the wiring area.

18. The array substrate of claim 2, wherein the anti-static ring circuit includes a ring circuit composed of four diodes, wherein the ring circuit includes an input end and an output end.

19. The array substrate of claim 18, wherein the input end is coupled to the scan lines, and the output end is coupled to ground.

20. An array substrate, comprising:
a substrate, including a display area and a wiring area, the display area including a plurality of scan lines and a plurality of data lines, and a plurality of pixel units are disposed at intersections of the scan lines and the data lines; and
an electrostatic discharge protection circuit, disposed in the wiring area and coupled to the scan lines;
wherein, the electrostatic discharge protection circuit includes one electrostatic discharge circuit to be coupled to a plurality of scan lines, or the electrostatic discharge protection circuit includes a plurality of electrostatic discharge circuits to be correspondingly coupled to a plurality of scan lines.
